(19) United States
(12) Patent Application Publication
(10) Pub. No.: US 2025/0072099 A1
(43) Pub. Date: Feb. 27, 2025

(54) REDUCED RESIDUE AT ETCHED STRUCTURE SIDEWALLS

(71) Applicant: Taiwan Semiconductor Manufacturing Company, Ltd., Hsinchu (TW)

(72) Inventors: Kuei-Yu Kao, Hsinchu (TW); Chiung-Yu Cho, Hsinchu (TW); Ming-Ching Chang, Hsinchu (TW)

(73) Assignee: Taiwan Semiconductor Manufacturing Company, Ltd., Hsinchu (TW)

(21) Appl. No.: 18/455,211

(22) Filed: Aug. 24, 2023

(51) Int. Cl. H01L 21/8234; H01L 21/311; H01L 29/06; H01L 29/417; H01L 29/423; H01L 29/66; H01L 29/775; H01L 29/786

(52) U.S. Cl. CPC H01L 21/823481; H01L 21/31144; H01L 29/0673; H01L 29/41775; H01L 29/42392; H01L 29/66545; H01L 29/775; H01L 29/78696

(57) ABSTRACT

Provided are devices and methods for forming devices. A method includes forming structures over a substrate; forming a layer between the structures; performing a first etch process to recess the layer to a surface having a serrated profile; optionally forming a film or films over the surface, wherein the film or films retain the serrated profile; depositing a material over the substrate; selectively masking the material to define a masked portion of the material and an unmasked portion of the material; and performing a second etch process to etch a portion of the material and form the material with a sidewall, wherein the second etch process uncovers the serrated profile, and wherein during the second etch process ions are reflected from the serrated profile.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device, in accordance with some embodiments.

FIG. 2 is a vertical cross-sectional view of the semiconductor device of FIG. 1, taken along the X-axis and Z-axis in FIG. 1.

FIG. 3 is a horizontal cross-sectional view of the semiconductor device of FIG. 1, taken along the X-axis and Y-axis in FIG. 1

FIG. 4 is a flow chart illustrating a method, in accordance with some embodiments.

FIGS. 5-25 are views of the structure of the semiconductor device during successive stages of fabrication, in accordance with some embodiments, wherein FIG. 5 is a perspective view, FIG. 6 is a perspective view of a successive stage, FIG. 7 is a cross-sectional view taken along the X-axis of a successive stage, FIG. 8 is a cross-sectional view taken along the X-axis of a successive stage, FIG. 9 is a cross-sectional view of a focused portion of FIG. 8 and at the same stage as FIG. 8, FIG. 10 is a cross-sectional view taken along the X-axis of a successive stage, FIGS. 11-13 illustrate the device at a same successive stage wherein FIG. 11 is a perspective view, FIG. 12 is a cross-sectional view of FIG. 11 taken along the X-axis, FIG. 13 is a cross-sectional view of FIG. 11 taken along the X-axis, FIGS. 14-17 illustrate the device at a same successive stage, wherein FIG. 14 is a perspective view, FIG. 15 is a cross-sectional view of FIG. 14 taken along a Y-axis through a fin, FIG. 16 is a cross-sectional view of FIG. 14 taken along an X-axis immediately adjacent to the sacrificial gate structure and through the gate residue, and FIG. 17 is a cross-sectional view of FIG. 14 taken along a Y-axis immediately adjacent to the fin and through the gate residue, FIG. 18 is a perspective view of a successive stage, FIG. 19 is a perspective view of a successive stage, FIG. 20 is a cross-sectional view of the device at the stage of FIG. 19 taken along line 6-6, FIG. 21 is a perspective view of a successive stage, FIG. 22 is a cross-sectional view of the device at the stage of FIG. 21 taken along line 7-7, FIG. 23 is a cross-sectional view taken along a Y-axis of a successive stage, FIG. 24 is a cross-sectional view taken along a Y-axis of a successive stage, and FIG. 25 is a cross-sectional view taken along a Y-axis of a successive stage, all in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. As used herein, “directly over” refers to a vertical alignment of features such that when an overlying feature that is directly over an underlying feature, a vertical axis passes through both features. In addition, the present disclosure may repeat reference numerals and/or letters in the various examples. This repetition is for the purpose of simplicity and clarity and does not in itself dictate a relationship between the various embodiments and/or configurations discussed.

As used herein, “positive slope” and “negative slope” refer to the typical reference system in which a positive slope is defined by an increase in a vertical or Z direction with an increase in the lateral or X direction and a negative slope is defined by an decrease in a vertical or Z direction with an increase in the lateral or X direction.

Further, spatially relative terms, such as “directly over”, “over”, “overlying”, “above”, “upper”, “top”, “under”, “underlying”, “beneath”, “below”, “lower”, “bottom”, “side”, “positive slope” and “negative slope” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material layer” is a layer that includes at least 50 wt. % of the identified material, for example at least 60 wt. % of the identified material, or at least 75 wt. % of the identified material, or at least 90 wt. % of the identified material; and a layer that is a “material” includes at least 50 wt. % of the identified material, for example at least 60 wt. % of the identified material, at least 75 wt. %, at least 90 wt. %, at least 99 wt. %, or at least 99.9 wt. % of the identified material. For example, certain embodiments, each of a titanium nitride layer and a layer that is titanium nitride is a layer that is at least 50 wt. %, at least 60 wt. %, at least 75 wt. %, at least 90 wt. %, at least 99 wt. %, or at least 99.9 wt. % titanium nitride.

For the sake of brevity, well-known techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

As described herein, a method is performed to reduce residue on the sidewall of a structure after an etching process. Specifically, the method reduces residue at the intersection or junction of two sidewalls, i.e., at an internal corner, such as an internal corner having an internal angle of 90 degrees. For example, during formation of a sacrificial structure, such as a sacrificial gate, sacrificial material is deposited over fin structures and over the isolation material located between fin structures. Then, the sacrificial material is patterned to form the sacrificial gate. During this process, an undesirable residue of the sacrificial material may remain at the junction of the sidewall of the fin structure and the sidewall of the sacrificial gate. Further, such residue may cause the improper formation of later-formed structures, leading to electrical shorts or other issues.

In embodiments herein, before deposition of the sacrificial material, the isolation material is recessed to a serrated surface. For example, the recessed surface of the isolation material has a wave shape or pattern and includes alternating crests and troughs. Then, the sacrificial material is deposited over the fin structures and over the recessed isolation material. During the etch process used to pattern the sacrificial material, after removing selected portions of the sacrificial material, plasma ions are reflected off of the wave shape and toward the sacrificial gate sidewall and/or toward the fin structure sidewall. Thus, the amount of unwanted residue is reduced or eliminated.

Embodiments of the present disclosure offer advantages over the existing art, though it is understood that other embodiments may offer different advantages, not all advantages are necessarily discussed herein, and no particular advantage is required for all embodiments.

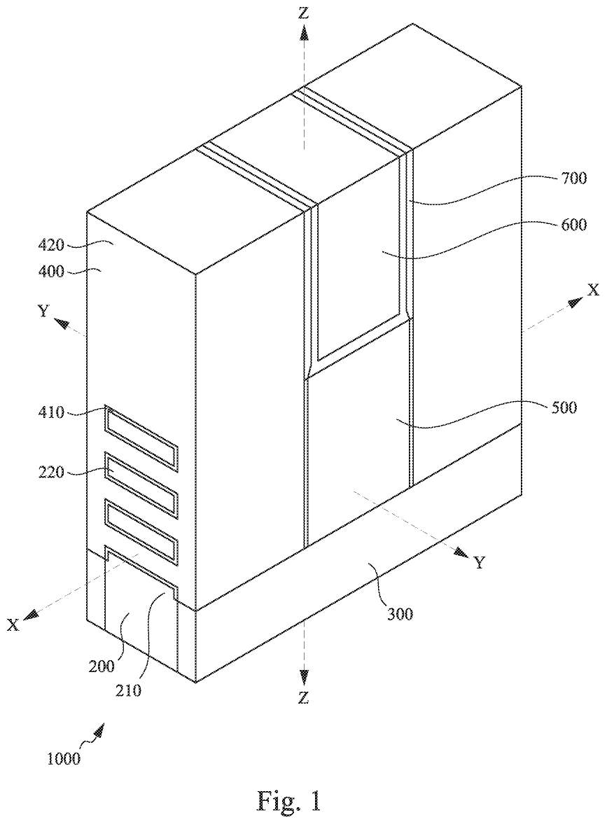

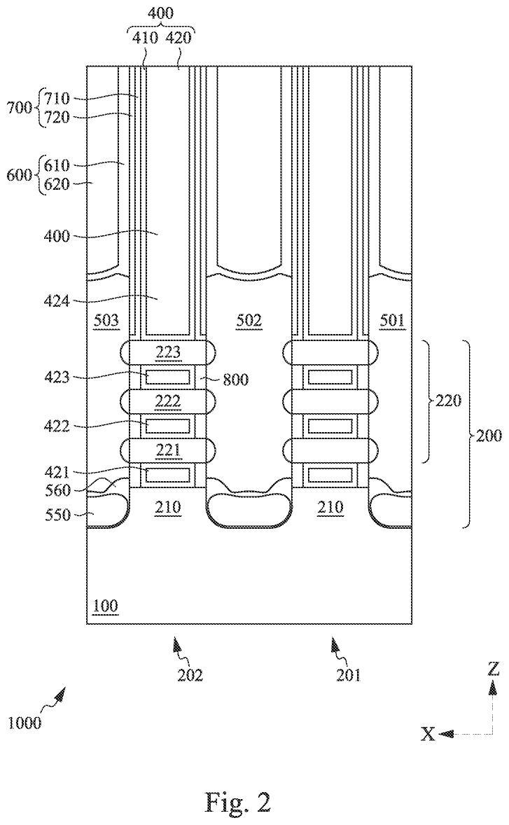

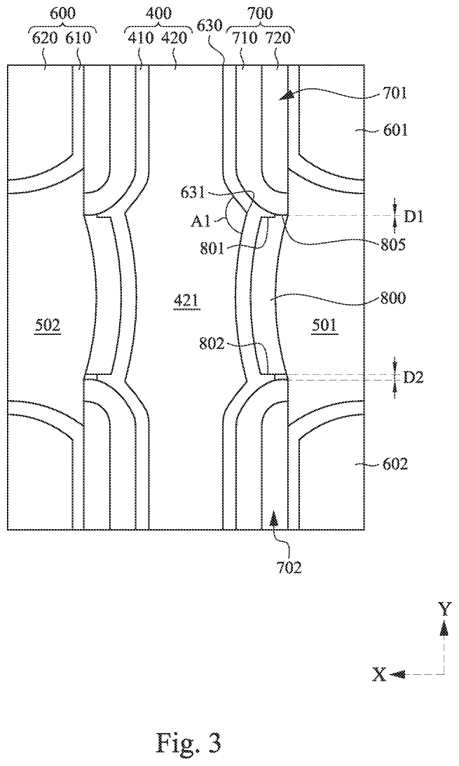

For purposes of the discussion that follows, FIGS. 1-3 illustrate a portion of a semiconductor device 1000 fabricated according to methods described herein. FIG. 1 is a perspective view, FIG. 2 is a cross-sectional view taken along the X and Z axes of FIG. 1, and FIG. 3 is a cross-sectional view taken along the X and Y axes of FIG. 1.

While FIGS. 1-3 illustrate the semiconductor device 1000 as a gate-all-around (GAA) device, device 1000 may be formed as another type of semiconductor device. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as a “nanosheet”.

As shown in FIGS. 1-3, device 1000 includes a substrate 100, such as a semiconductor substrate. In some embodiments, the substrate 100 may be formed from and include silicon. Alternatively or additionally, the substrate 100 includes another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP. In yet another alternative, the substrate 100 is a semiconductor on insulator (SOI). The plurality of conductive and non-conductive thin films may comprise an insulator or a conductive material. For example, the conductive material comprises a metal such as aluminum (Al), copper (Cu), tungsten (W), nickel (Ni), titanium (Ti), and platinum (Pt) and, thereof an alloy of the metals and other conductive substances such as nitrides (e.g., titanium nitride (TiN), tantalum nitride (TaN)) and carbides (e.g., titanium carbide (TiC), tantalum carbide (TaC)). The insulator material may include silicon oxide and silicon nitride.

As shown in FIGS. 1-3, the device 1000 further includes fin structures 200. The fin structures 200 may be formed from the substrate 100. For example, the fin structures 200 may include a mesa portion 210 that is formed from the substrate 100. Further, the fin structures 200 may include semiconductor nanosheets 220, including nanosheets 221, 222, and 223. While FIGS. 1-3 illustrate three nanosheets 220, the fin structures 200 of device 1000 may include any suitable number of nanosheets 220. Each fin structure 200 may include a lowest semiconductor nanosheet 221 distanced from a mesa portion 210 in the vertical Z-direction, and nanosheets 222 and 223 distanced from the lowest semiconductor nanosheet 221 in the vertical Z-direction.

Fin structures 200 extend in the X-direction and are spaced from one another in the Y-direction.

Also, the device 1000 may include isolation features 300, such as shallow trench isolation (STI) regions, adjacent to each fin structure 200. The isolation regions 300 extend in the X-direction and a spaced from one another in the Y-direction. In some embodiments, the isolation features 300 include silicon oxide. The isolation features 300 may include other suitable materials.

As shown in FIGS. 1-3, the device 1000 also includes gate structures 400. The gate structures extend in the Y-direction and a spaced from one another in the X-direction. In some embodiments, the gate structure 400 is a high-K metal gate structure, and includes a high-K gate dielectric layer 410 and a metal gate electrode 420. As shown, the high-K gate dielectric layer 410 may be formed on and around the semiconductor nanosheets 220 and on the mesa portion 210 of the fin structure 200, above the isolation feature 300.

Thus, the gate structure 400 may include a portion 421 between the lowest nanosheet 221 and the mesa portion 210, a portion 422 between the middle nanosheet 222 and the lower nanosheet 221, a portion 423 between the uppermost nanosheet 223 and the middle nanosheet 222, and an upper portion 424 located above the uppermost nanosheet 223.

As shown in FIGS. 1-3, device 1000 further includes source/drain regions 500. As used herein, “source/drain region(s)” may refer to a source region or a drain region, individually or collectively depending on the context. Source/drain regions 500 include a first source/drain region 501 distanced from a second source/drain region 502 and a third source/drain region 503 in the lateral X-direction, as shown in FIG. 2.

As further shown in FIG. 2, the nanosheets 220 extend in the lateral X-direction between adjacent source/drain regions 500.

As further shown in FIG. 2, a bottom epitaxial region 550 may be located under the source/drain regions 500.

Also, inner spacers 800 are located laterally between the gate portions 421, 422, and 423 and the source/drain regions 500.

As further shown in FIGS. 1-3, a dielectric structure 600 is located vertically over each source/drain region 500. The dielectric structures 600 may include a layer 610 and a layer 620. For example, layer 610 may be an etch stop layer, and layer 620 may be an interlayer dielectric material.

In FIGS. 1-3, a spacer structure 700 is located between each dielectric structure 600 and gate structure 400. The spacer structure 700 may include a first layer 710 and a second layer 720. For example, the first layer 710 may be a first spacer layer and the second layer 720 may be a second spacer layer.

Referring to FIG. 3, dielectric structures 600 include a first dielectric structure or region 601 distanced from a second dielectric structure or region 602 in the longitudinal Y-direction. As shown, source/drain region 501 is located between the first dielectric region 601 and the second dielectric region 602 in the longitudinal Y-direction.

FIG. 3 illustrates that the inner spacer 800 separates the first source/drain region 501 from the lowest portion 421 of the gate structure 400 in the lateral X-direction, that the first spacer structure 701 separates the first dielectric region 601 from the gate structure 400 in the lateral X-direction, and that the second spacer structure 702 separates the second dielectric region 602 from the gate structure 400 in the lateral X-direction.

As a result of the fabrication methods described herein, device 1000 is formed with reduced vulnerability to shorting between the source/drain regions 500 and the gate structure 400. Specifically, a distance in the longitudinal Y-direction between the inner spacer 800 and the adjacent spacer structures 700 is reduced. For example, in FIG. 3, inner spacer 800 extends in the longitudinal Y-direction to and terminates at a first end 801, and extends in the longitudinal Y-direction to and terminates at a second end 802.

The first end 801 is distanced from the first spacer structure 701 by a minimum distance D1. In some embodiments, the minimum distance D1 is from zero, i.e., the inner spacer 800 contacts the first spacer structure 701, to 2 nanometers (nm). The second end 802 is distanced from the second spacer structure 702 by a minimum distance D2. In some embodiments, the minimum distance D2 is from zero, i.e., the inner spacer 800 contacts the second spacer structure 702, to 2 nanometers (nm).

In some embodiments, the minimum first distance D1 between the spacer structure 701 and the inner spacer 800 in the longitudinal Y-direction is located at an interface 805 between the inner spacer 800 and spacer structure 700, and the metal gate 400 extends toward the interface 805 to a vertical edge 631. As shown, a lateral profile of the edge 631 of the metal gate 400 has an internal angle A1 of greater than 100 degrees. For example, internal angle A1 may be from 100 to 120 degrees. In some embodiments, internal angle A1 may be at least 100, at least 105, at least 110, or at least 115 degrees and may be at most 120, at most 115, at most 110, or at most 105 degrees.

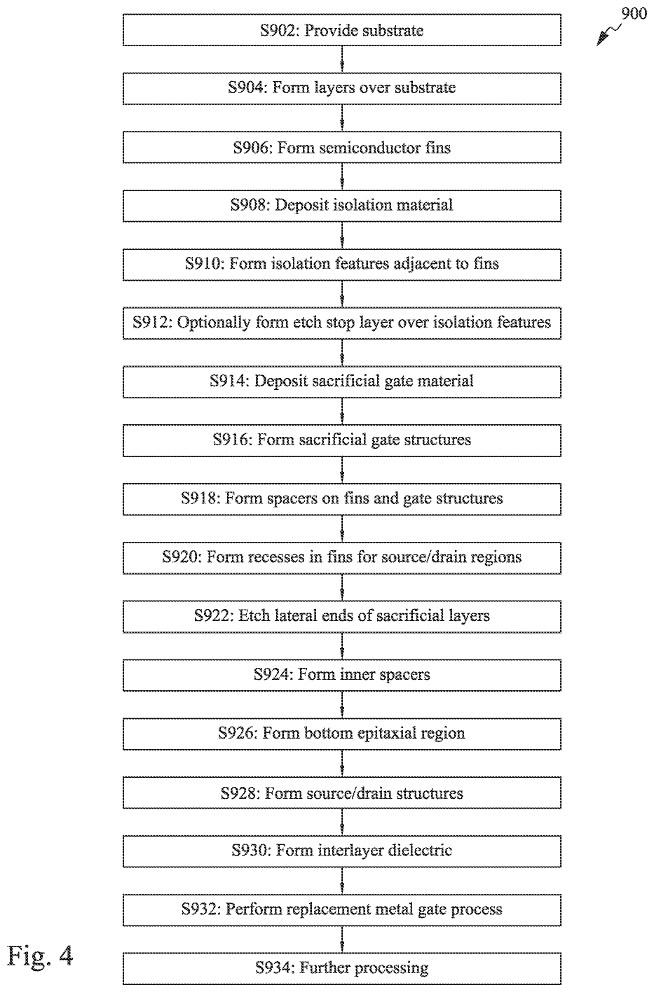

Referring now to FIG. 4, a method 900 for forming a structure, such as a multi-gate device 1000 according to embodiments in FIGS. 1-3, is illustrated in a flow chart, according to various aspects of the present disclosure.

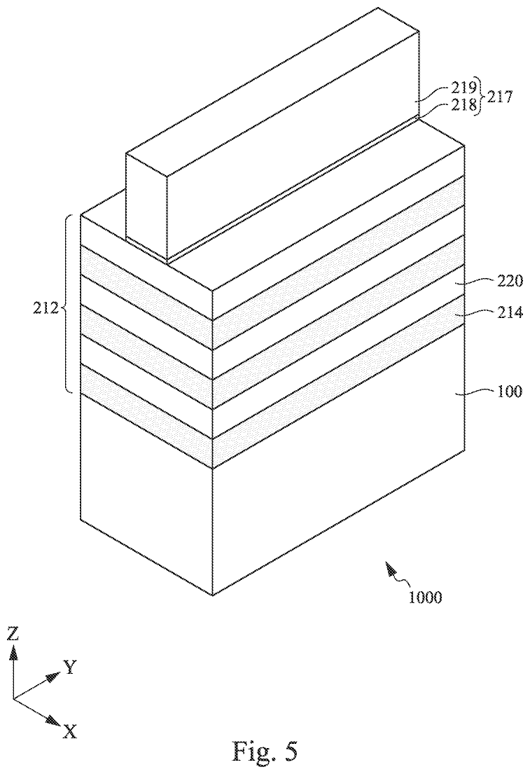

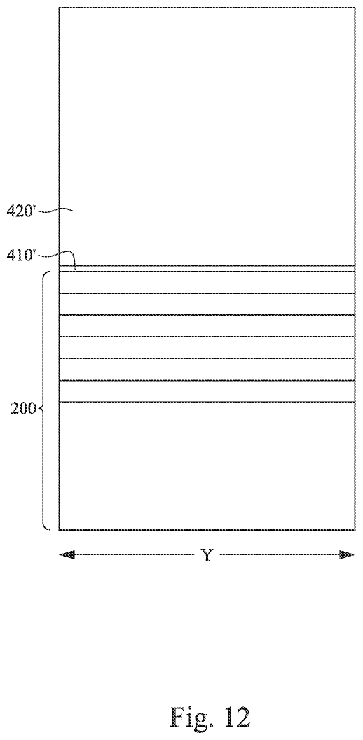

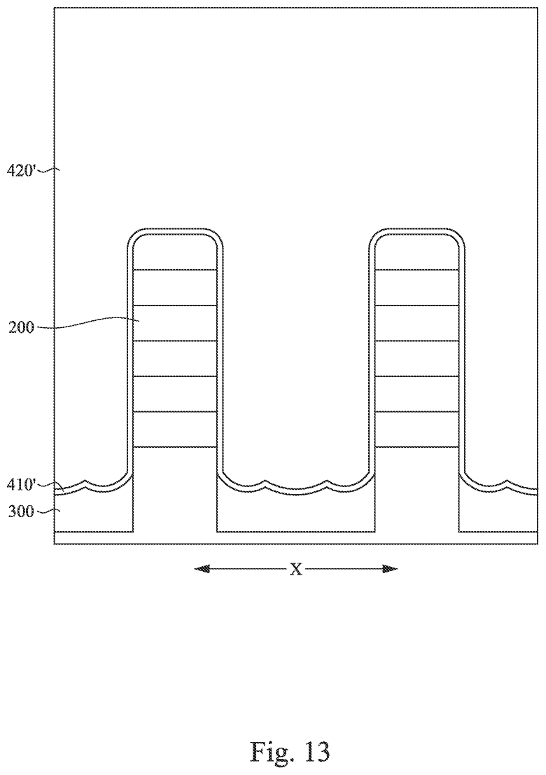

FIG. 4 is described in conjunction with FIGS. 5-25, which illustrate a semiconductor device 1000 at various stages of fabrication in accordance with some embodiments of the present disclosure of the method 900. The method 900 is merely an example, and is not intended to limit the present disclosure beyond what is explicitly recited in the claims. Additional steps may be provided before, during, and after method 900, and some of the steps described can be moved, replaced, or eliminated for additional embodiments of method 900. Additional features may be added in the semiconductor device depicted in the Figures and some of the features described below can be replaced, modified, or eliminated in other embodiments of the semiconductor device.

As with the other method embodiments and devices discussed herein, it is understood that parts of the semiconductor device 1000 may be fabricated by typical semiconductor technology process flow, and thus some processes are only briefly described herein. Further, the semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the devices include a plurality of semiconductor devices (e.g., transistors), including PFETs, NFETs, etc., which may be interconnected.

At operation S902, the method 900 (FIG. 4) provides a substrate 100, as shown in FIG. 5. In some embodiments, the substrate 100 may be a semiconductor substrate such as a silicon (Si) substrate. The substrate 100 may include various layers, including conductive or insulating layers formed on a semiconductor substrate. The substrate 100 may include various doping configurations depending on design requirements as is known in the art. For example, different doping profiles (e.g., p-well, n-well) may be formed on the substrate 100 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 100 includes a single crystalline semiconductor layer on at least its surface portion. The substrate 100 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 100 may include a compound semiconductor and/or an alloy semiconductor. In the illustrated embodiment, the substrate 100 is made of crystalline Si.

As shown in FIG. 5, at operation S904, the method 900 (FIG. 4) forms one or more epitaxial layers over the substrate 100. In some embodiments, an epitaxial stack 212 is formed over the substrate 100. The epitaxial stack 212 includes epitaxial layers 214 of a first composition interposed by epitaxial layers 220 of a second composition. The first and second composition may be different. Embodiments are possible including those that provide for a first composition and a second composition having different oxidation rates and/or etch selectivity. In an embodiment, the epitaxial layers 214 are SiGe and the epitaxial layers 220 are silicon. In embodiments wherein the epitaxial layer 214 includes SiGe and the epitaxial layer 220 includes silicon, the silicon oxidation rate is less than the SiGe oxidation rate. It is noted that three layers of epitaxial layers 214 and three layers of epitaxial layers 220 are illustrated in FIG. 5, which is for illustrative purposes only and not intended to be limiting beyond what is specifically recited in the claims. It can be appreciated that any number of epitaxial layers may be formed in the epitaxial stack 212; the number of layers depending on the desired number of channels regions for the GAA device 1000. In some embodiments, the number of epitaxial layers 220 is between two and ten, such as six or seven.

In some embodiments, the epitaxial layer 214 has a thickness ranging from 5 to 15 nm. The epitaxial layers 214 may be substantially uniform in thickness. In some embodiments, the epitaxial layer 220 has a thickness ranging from 5 to 15 nm. In some embodiments, the epitaxial layers 220 of the stack are substantially uniform in thickness. As described in more detail below, the epitaxial layer 220 may serve as channel region(s) for a subsequently formed multi-gate device 1000 and has a thickness chosen based on device performance considerations. The epitaxial layer 214 may serve to define a gap between adjacent channel region(s) for a subsequently formed multi-gate device 1000 and has a thickness chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 220, include the same material as the substrate 100. In some embodiments, the epitaxially grown layers 214 and/or 220 include a different material than the substrate 100. As stated above, in at least some examples, the epitaxial layer 214 includes an epitaxially grown Si₁₋ₓGeₓ layer (wherein x is from 0.10 to 0.55 and the epitaxial layer 220 includes an epitaxially grown silicon (Si) layer. Alternatively, in some embodiments, either of the epitaxial layers 214 and 220 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 214 and 220 may be chosen based on providing differing oxidation, etch selectivity properties. In various embodiments, the epitaxial layers 214 and 220 are substantially dopant-free (i.e., having an extrinsic dopant concentration from 0 cm⁻³ to 1×10¹⁷ cm⁻³), where for example, no intentional doping is performed during the epitaxial growth process. In some embodiments, the bottom layer and the top layer of the epitaxial stack 212 are SiGe layers (not shown). In alternative embodiments, the bottom layer of the epitaxial stack 212 is a Si layer and the top layer of the epitaxial stack 212 is a SiGe layer (not shown).

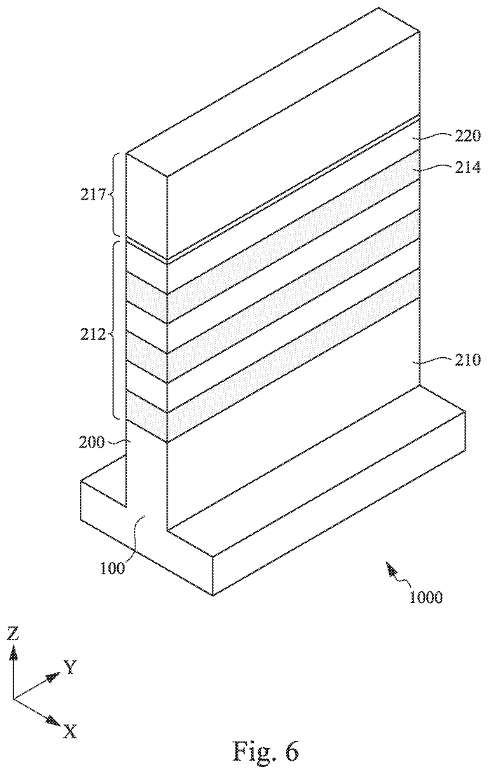

As shown in FIG. 6, at operation S906, the method 900 (FIG. 4) patterns the epitaxial stack 212 to form semiconductor fins 200. In some embodiments, the operation S906 includes forming a mask layer 217 over the epitaxial stack 212, as shown in FIG. 5. The mask layer 217 includes a first mask layer 218 and a second mask layer 219. The first mask layer 218 may be a pad oxide layer made of a silicon oxide, which may be formed by a thermal oxidation. The second mask layer 219 may be made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process. The mask layer 217 is patterned into a mask pattern by using patterning operations including photolithography and etching.

As shown in FIG. 6, operation S906 subsequently patterns the epitaxial stack 212 in an etching process, such as a dry etch (e.g., reactive ion etching), a wet etch, and/or other suitable process, through openings defined in the patterned mask layer 217. The stacked epitaxial layers 214 and 220 are thereby patterned into the fin 200. While FIG. 6 illustrates the formation of one fin 200, any suitable number of the fins may be formed. Trenches are etched between adjacent fins 200.

In various embodiments, each fin 200 includes an upper portion of the interleaved epitaxial layers 214 and 220, and a bottom portion, or mesa portion 210, that is formed from the etched substrate 100. Each fin 200 protrudes upwardly in the Z-direction from the substrate 100 and extends lengthwise in the Y-direction. Sidewalls of each fin 200 may be straight or inclined (not shown). Additional fins would be spaced apart along the X-direction. The fins 200 may have a same width or different widths.

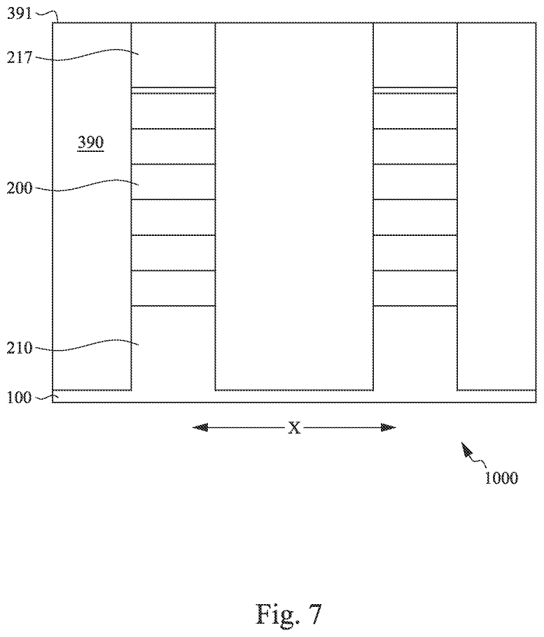

As shown in FIG. 7, at operation S908, the method 900 (FIG. 4) deposits an isolation material 390 over and around the semiconductor fins 200. Specifically, the deposition process fills the trenches between adjacent fins 200, covering the sidewalls of the fins 200, and over the mask layer 217. The dielectric material 390 may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material 390 may be deposited by any suitable technique including thermal growth, flowable CVD (FCVD), HDP-CVD, PVD, ALD, and/or spin-on techniques.

As shown in FIG. 7, the method 900 includes planarizing the isolation material 390 to a planarized surface 391 by using, for example, chemical mechanical planarization (CMP), until top surfaces of the mask layer 217 are revealed.

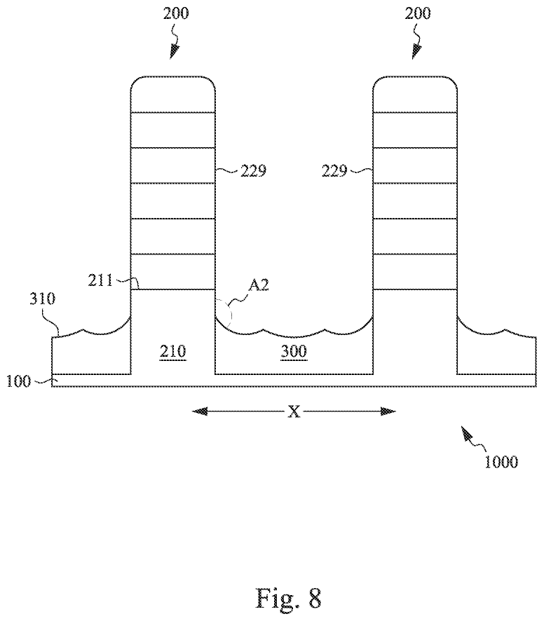

As shown in FIG. 8, at operation S910, the method 900 (FIG. 4) recesses the isolation material 390 to form the shallow trench isolation (STI) features 300 (also denoted as STI features 300). In the illustrated embodiment, the STI features 300 are formed on the substrate 100. As shown, the STI features 300 have an uppermost surface 310. In some embodiments, the uppermost surface 310 has a serrated profile, as shown. In some embodiments, the uppermost surface 310 has a wave shape, as shown. The recessed surface 310 extends between and contacts the sidewalls 229 of adjacent fin structures 200. In some embodiments, the recessed surface 310 contacts the mesa portion 210 of each fin 200, at a location below the uppermost surface 211 of the mesa portion 210.

As shown in FIG. 8, the recessed surface 310 contacts each sidewall 229 of the fin 200 at an angle A2. In some embodiments, angle A2 is from 120 to 160 degrees. For example, angle A2 may be at least 120, at least 125, at least 130, at least 135, at least 140, at least 145, at least 150, or at least 155 degrees. Further, angle A2 may be at most 125, at most 130, at most 135, at most 140, at most 145, at most 150, at most 155, or at most 160 degrees.

In some embodiments, the etching technique used to recess the isolation material to form the isolation features 300 includes a chemical etch and a plasma etch. In some embodiments, the etching technique used to recess the isolation features 300 includes a cycle or cycles of a chemical etch and a plasma etch. For example, the etching technique may include from one to five cycles of a chemical etch and a plasma etch. In one embodiment, the etching technique includes three cycles of a chemical etch and a plasma etch.

In some embodiments, the etching technique used to recess the isolation features 300 uses an etchant gas selected from NH3, NF3, HBr, and H2.

In some embodiments, the etching technique used to recess the isolation features 300 uses a passivation gas selected from N2 and O2 for selectivity.

In some embodiments, the etching technique used to recess the isolation features 300 uses a dilute gas selected from He, Ar, and N2.

In some embodiments, the etching technique used to recess the isolation features 300 is performed at a power of from 10 to 4000 Watts.

In some embodiments, the etching technique used to recess the isolation features 300 is performed at a pressure of from 10 mTorr to 3 Torr.

In some embodiments, the etching technique used to recess the isolation features 300 is performed with a gas flow of from 20 to 3000 standard cubic centimeter per minute (sccm).

In an embodiment, the etching technique used to recess the isolation material to form the isolation features 300 selectively removes the isolation material 330 without etching the fins 200. The mask layer 217 (shown in FIG. 7) may be removed before, during, and/or after the recessing of the isolation features 300. In some embodiments, the mask layer 217 is removed by the CMP process performed prior to the recessing of the isolation features 300. In some embodiments, the mask layer 217 is removed by an etchant used to recess the isolation features 300.

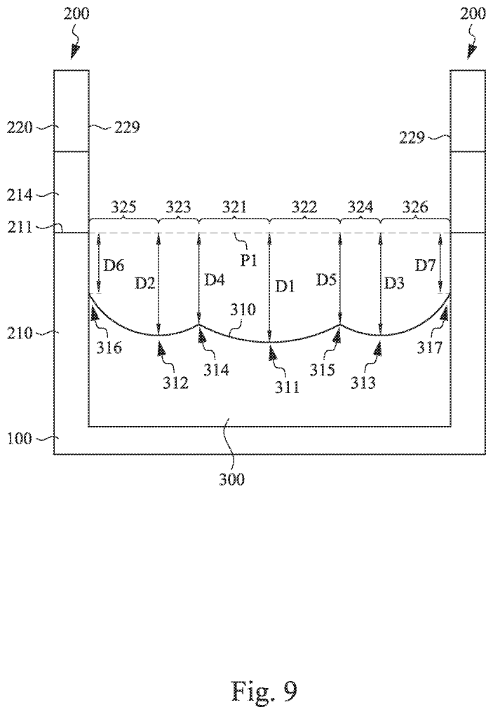

FIG. 9 provides a focused view of an isolation feature 300 located between adjacent fins 200. Specifically, FIG. 9 illustrates the serrated profile or wave shape of the surface 310 of the isolation feature 300.

As shown, the surface 310 includes a terminal crest 316, or peak, abutting the sidewall 229 of a fin 200 and a terminal crest 317, or peak, abutting the sidewall 229 of a fin 200. Further, the surface 310 includes an intermediate crest 314, or peak, located between the terminal crest 316 and the terminal crest 317; and includes an intermediate crest 315, or peak, located between the intermediate crest 314 and the terminal crest 317. The distance between terminal crest 316 and intermediate crest 314 may be equal to the distance between terminal crest 317 and intermediate crest 315.

As shown, the surface 310 includes a terminal trough 312, or nadir, located between the terminal crest 316 and the intermediate crest 314. Further, the surface 310 includes a terminal trough 313 located between the terminal crest 317 and the intermediate crest 315. Also, the surface 310 includes a central trough 311 located between the intermediate crest 314 and the intermediate crest 315. The distance between central trough 311 and terminal trough 312 may be equal to the distance between central trough 311 and terminal trough 313.

As shown, each of the troughs and crests is located at a vertical distance (in the Z-direction) from a horizontal plane P1 defined by the uppermost surface 211 of the mesa portion 210 of a fin 200 or of adjacent fins 200.

The central trough 311 is located at a vertical distance D1 from the plane P1. In some embodiments, the vertical distance D1 is from 15 to 35 nm. For example, vertical distance D1 may be at least 15, at least 20, at least 25, or at least 30 nm. Further, vertical distance D1 may be at most 20, at most 25, at most 30, or at most 35 nm.

In embodiments in which the fins 200 are formed with a larger pitch, the vertical distance D1 is from 25 to 45 nm. For example, vertical distance D1 may be at least 25, at least 30, at least 35, or at least 40 nm. Further, vertical distance D1 may be at most 30, at most 35, at most 40, or at most 45 nm.

The intermediate trough 312 is located at a vertical distance D2 from the plane P1. The intermediate trough 313 is located at a vertical distance D3 from the plane P1. The vertical distances D2 and D3 may be the same or may be different. In some embodiments, the vertical distance D2 or D3 is from 10 to 20 nm. For example, vertical distance D2 or D3 may be at least 10, at least 12.5, at least 15, or at least 17.5 nm. Further, vertical distance D2 or D3 may be at most 20, at most 17.5, at most 15, or at most 12.5 nm.

In embodiments in which the fins 200 are formed with a larger pitch, the vertical distance D2 or D3 is from 20 to 30 nm. For example, vertical distance D2 or D3 may be at least 20, at least 22.5, at least 25, or at least 27.5 nm. Further, vertical distance D2 or D3 may be at most 30, at most 27.5, at most 25, or at most 22.5 nm.

The intermediate crest 314 is located at a vertical distance D4 from the plane P1. The intermediate crest 315 is located at a vertical distance D5 from the plane P1. The vertical distances D4 and D5 may be the same or may be different. In some embodiments, the vertical distance D4 or D5 is from 5 to 15 nm. For example, vertical distance D4 or D5 may be at least 5, at least 7.5, at least 10, or at least 12.5 nm. Further, vertical distance D4 or D5 may be at most 15, at most 12.5, at most 10, or at most 7.5 nm.

In embodiments in which the fins 200 are formed with a larger pitch, the vertical distance D4 or D5 is from 15 to 25 nm. For example, vertical distance D4 or D5 may be at least 15, at least 17.5, at least 20, or at least 22.5 nm. Further, vertical distance D4 or D5 may be at most 25, at most 22.5, at most 20, or at most 17.5 nm.

The terminal crest 316 is located at a vertical distance D6 from the plane P1. The terminal crest 317 is located at a vertical distance D7 from the plane P1. The vertical distances D6 and D7 may be the same or may be different. In some embodiments, the vertical distance D6 or D7 is from 2 to 12 nm. For example, vertical distance D6 or D7 may be at least 2, at least 5, at least 7.5, or at least 10. Further, vertical distance D6 or D7 may be at most 12, at most 10, at most 7.5, or at most 5 nm.

In embodiments in which the fins 200 are formed with a larger pitch, the vertical distance D4 or D5 is from 5 to 20 nm. For example, vertical distance D6 or D7 may be at least 5, at least 7.5, at least 10, at least 12.5, at least 15, or at least 17.5. Further, vertical distance D6 or D7 may be at most 20, at most 17.5, at most 15, at most 12.5, at most 10, or at most 7.5 nm.

In FIG. 9, the surface 310 has a negative slope from the terminal crest 316 to the intermediate trough 312, a positive slope from the intermediate trough 312 to the intermediate crest 314, a negative slope from the intermediate crest 314 to the central trough 311, a positive slope from the central trough 311 to the intermediate crest 315, a negative slope from the intermediate crest 315 to the intermediate trough 313, and a positive slope from the intermediate trough 313 to the terminal crest 317.

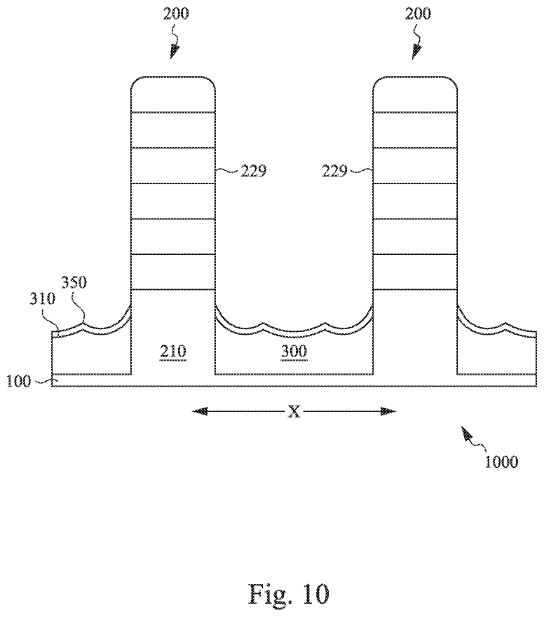

As shown in FIG. 10, at operation S912, the method 900 (FIG. 4) may optionally include forming a layer 350 over the isolation features 300. In some embodiments, the layer 350 is an etch stop layer. For example, the layer 350 may be a dielectric material, such as silicon oxide. In some embodiments, the layer 350 is conformally deposited with a thickness of from 2 to 3 nm. The layer 350 is conformal and thin and retains the serrated profile or wave shape of the underlying isolation feature 300, as shown in FIG. 10.

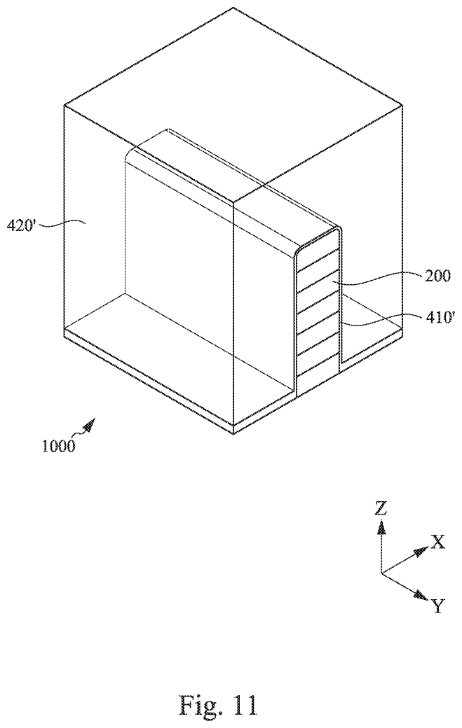

As shown in FIGS. 11-13, at operation S914, the method 900 (FIG. 4) deposits sacrificial (dummy) gate material over the fin structures 200 and isolation features 300.

Deposition of the sacrificial gate material may include first conformally depositing a sacrificial gate dielectric layer 410′ over the fins 200 and isolation region 300. A sacrificial gate electrode layer 420′ is then blanket deposited on the sacrificial gate dielectric layer 410′. It is noted that the sacrificial gate dielectric layer 410′ may be deposited instead of the layer 350. Thus, in embodiments using a sacrificial gate dielectric layer 410′, the layer 350 need not be deposited. The sacrificial gate dielectric layer 410′ is conformal and thin and retains the serrated profile or wave shape of the underlying isolation feature 300.

The sacrificial gate dielectric layer 410′ may include silicon oxide, silicon nitride, or a combination thereof. The thickness of the sacrificial gate electrode layer 420′ may be from 100 to 200 nm in some embodiments. The sacrificial gate electrode layer 420′ includes silicon such as polycrystalline silicon or amorphous silicon. The thickness of the sacrificial gate dielectric layer 410′ may be from 1 to 5 nm in some embodiments, such as from 2 to 3 nm. In some embodiments, the sacrificial gate electrode layer 420′ is subjected to a planarization operation. The sacrificial gate dielectric layer 410′ and the sacrificial gate electrode layer 420′ are deposited using CVD, including LPCVD and PECVD, PVD, ALD, or other suitable process.

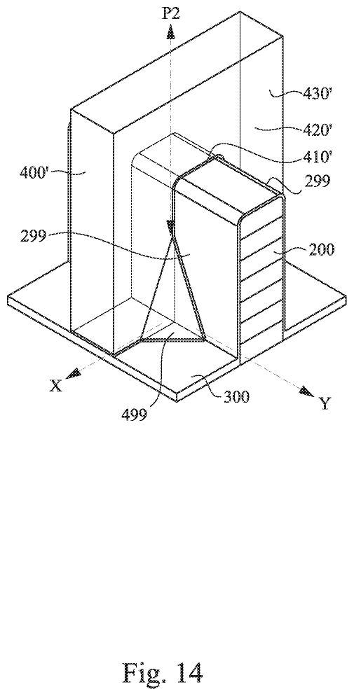

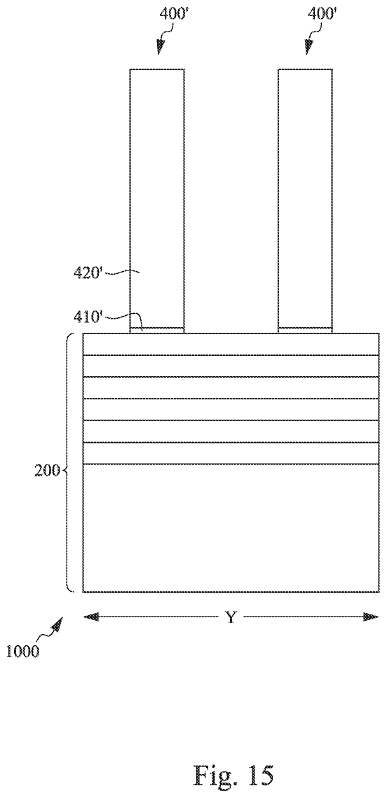

As shown in FIGS. 14-15, at operation S916, the method 900 (FIG. 4) forms sacrificial (dummy) gate structures 400′. Specifically, operation S916 includes etching portions of the sacrificial gate material 420′ and sacrificial gate dielectric 410′ to form sacrificial gates structures 400′.

The sacrificial gate structures 400′ are formed over portions of the fin 200 which are to be channel regions. The sacrificial gate structures 400′ may extend over a number of adjacent fins (not shown). The sacrificial gate structures 400′ lie directly over and define the channel regions of the GAA devices to be formed. Each of the sacrificial gate structures 400′ includes a sacrificial gate dielectric 410′ and a sacrificial gate electrode 420′ over the sacrificial gate dielectric 410′. As shown, the sacrificial gate structures 400′ extend lengthwise in the X-direction and are spaced apart in the Y-direction.

To form the sacrificial (dummy) gate structures 400′, a mask layer (not shown) may be formed over the sacrificial gate electrode layer 420′. The mask layer may include multiple layers including a silicon oxide layer and a silicon nitride layer. Subsequently, a patterning operation is performed on the mask layer, and the sacrificial gate electrode layers 420′ and the sacrificial gate dielectric layer 410′ are patterned into the sacrificial gate structures 400′, including sacrificial gate dielectric layer 410′ and sacrificial gate electrode 420′.

Etching of the sacrificial gate layers to form the sacrificial (dummy) gate structures 400′ may include a plasma etching process, with the sacrificial gate dielectric 410′ as an etch stop layer, to etch the sacrificial gate material 420′, followed by a wet clean process to etch the sacrificial gate dielectric 410′. After the wet clean process, a native oxide layer 299 may be formed on the fin structure 200.

As shown in FIG. 14, the etch process for forming the sacrificial gate structure 400′ forms the sacrificial gate structure 400′ with a substantially planar sidewall 430′, defining a plane P2. In some embodiments, plane P2 is a vertical plane. As shown, a residue 499 of the sacrificial gate dielectric layer 410′ and the sacrificial gate electrode 420′ may remain at the intersection of the fin sidewall 229 and the sidewall 430′ of the sacrificial gate structure 400′. Embodiments herein provide for reducing or eliminating the residue 499. It is noted that the residue 499 in FIG. 14 is exaggerated in size for clarity of illustration.

For example, during the plasma etching process, plasma ions are directed at the sacrificial gate electrode layer 420′ and toward the isolation features 300. When portions of the sacrificial gate electrode layer 420′ overlying a region of the isolation feature 300 are removed, the plasma ions strike the optional layer 350 or sacrificial gate dielectric 410′ and are reflected. Due to the serrated profile or wave shape of such layers 350 or 410′, the plasma ions are reflected laterally and/or longitudinally i.e., in the X-direction and/or Y-direction. Specifically, the plasma ions may be reflected toward the sidewall 229 of the fin 200 and/or toward the sidewall 430′ of the sacrificial gate 400′ being formed. As a result, the ion bombardment is increased at the intersection of the fin sidewall 229 and the sidewall 430′ of the sacrificial gate 400′. The plasma bombardment increases the physical etching of material.

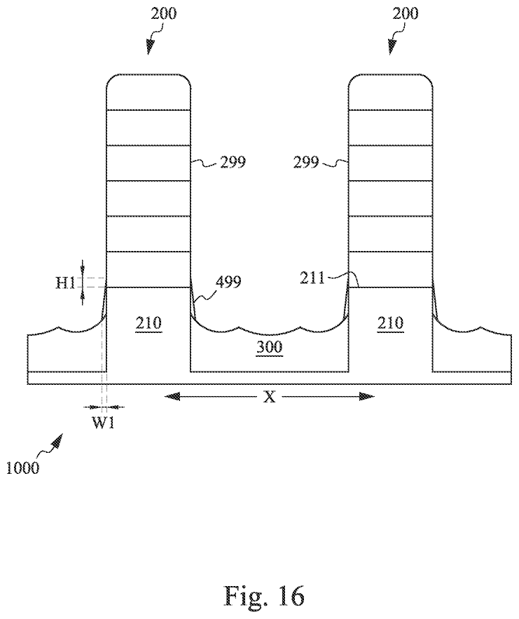

FIG. 16 illustrates the sacrificial gate residue 499 adjacent the fins 200 in the X-direction. As shown, the sacrificial gate residue 499 extends in the X-direction from the sidewalls 229 of the fins 200. Each sacrificial gate residue 499 has a maximum lateral width W1, in the X-direction.

In some embodiments, the maximum lateral width W1 is 4 nm. For example, the maximum lateral width W1 may be from 1 to 3 nm. In some embodiments, the maximum lateral width W1 is at least 1 nm, at least 1.5 nm, at least 2 nm, or at least 2.5 nm. In some embodiments, the maximum lateral width W1 is at most 1.5 nm, at most 2 nm, at most 2.5 nm, at most 3 nm, at most 3.5 nm, or at most 4 nm.

As further shown in FIG. 16, the sacrificial gate residue 499 extends in the Z-direction from the isolation feature 300 along the sidewalls 229 of the fins 200 to a vertical height H1 above the uppermost surface 211 of the mesa portion 210. Each sacrificial gate residue 499 has a maximum vertical height H1 of from 0 to 4 nm. For example, the maximum vertical height H1 is at least 0 nm, at least 0.5 nm, at least 1 nm, at least 1.5 nm, at least 2 nm, at least 2.5 nm, at least 3 nm, or at least 3.5 nm. In some embodiments, the maximum vertical height H1 is at most 0 nm, at most 0.5 nm, at most 1 nm, at most 1.5 nm, at most 2 nm, at most 2.5 nm, at most 3 nm, at most 3.5 nm, or at most 4 nm.

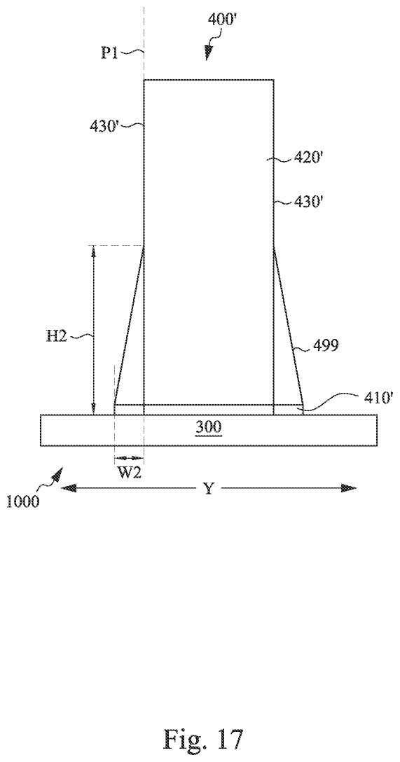

FIG. 17 illustrates the sacrificial gate residue 499 adjacent the sacrificial gate structures 400′ in the Y-direction. As shown, the sacrificial gate residue 499 extends in the Y-direction from the sidewalls 430′ of the sacrificial gate structures 400′. Each sacrificial gate residue 499 has a maximum longitudinal width W2, in the Y-direction.

In some embodiments, the maximum longitudinal width W2 is 4 nm. For example, the maximum longitudinal width W2 may be from 1 to 3 nm. In some embodiments, the maximum longitudinal width W2 is at least 1 nm, at least 1.5 nm, at least 2 nm, or at least 2.5 nm. In some embodiments, the maximum longitudinal width W2 is at most 1.5 nm, at most 2 nm, at most 2.5 nm, at most 3 nm, at most 3.5 nm, or at most 4 nm.

As further shown in FIG. 17, the sacrificial gate residue 499 extends in the Z-direction from the isolation feature 300 along the sidewalls 229 of the fins 200 to a height H2 above the isolation feature 300. Each sacrificial gate residue 499 has a maximum vertical height H2 of from 1 to 20 nm. For example, the maximum vertical height H2 is at least 1 nm, at least 2 nm, at least 3 nm, at least 4 nm, at least 5 nm, at least 6 nm, at least 7 nm, at least 8nm, at least 9 nm, at least 10 nm, at least 12.5 nm, at least 15 nm, or at least 17.5 nm. For example, the maximum vertical height H2 is at most 5 nm, at most 6 nm, at most 7 nm, at most 8 nm, at most 9 nm, at most 10 nm, at most 12.5 nm, at most 15 nm, at most 17.5 nm, or at most 20 nm.

As shown most clearly in FIG. 15, the after formation of the sacrificial gate structures 400′, each fin 200 is partially exposed between and on opposite sides of the sacrificial gate structures 400′, thereby defining source/drain (S/D) regions. As used herein, “source/drain region(s)” may refer to a source region or a drain region, individually or collectively depending on the context.

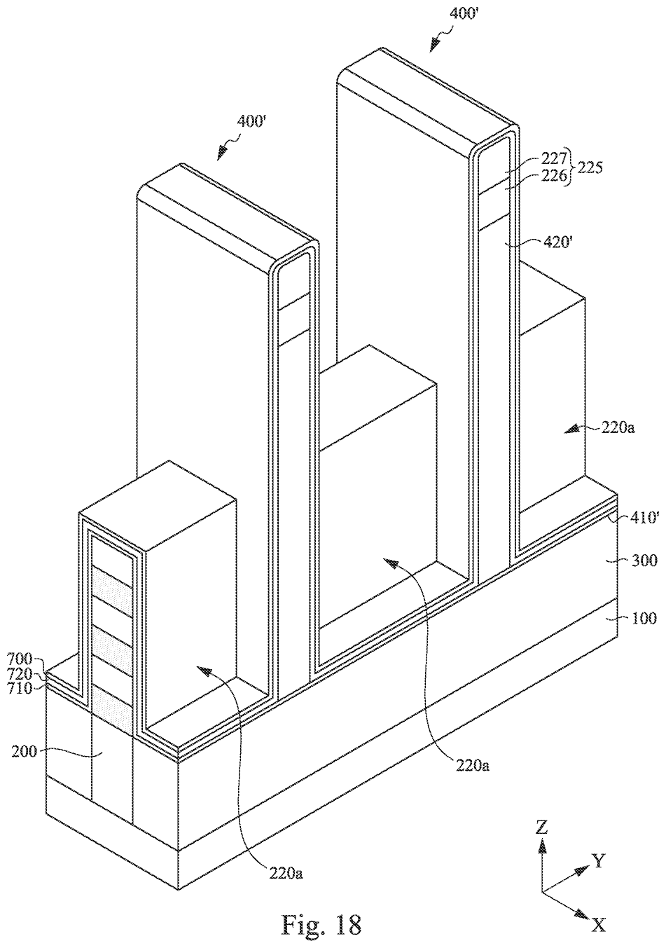

As shown in FIG. 18, at operation S918, the method 900 (FIG. 4) forms spacers 700 on sidewalls of the sacrificial gate structures 400′ and sidewalls of the fins 200 by depositing spacer materials and then etching.

While not shown in FIGS. 14-17, a mask layer 225 may be formed over the sacrificial gate electrode layer 420′ before patterning to form the sacrificial gates 400′. The mask layer 225 may include a mask layer 226 such as silicon oxide and a mask layer 227 such as silicon nitride. Subsequently, a patterning operation is performed on the mask layer 225, the sacrificial gate electrode layers and the sacrificial gate dielectric layer are patterned into the sacrificial gate structures 400′, including sacrificial gate dielectric layer 410′ and sacrificial gate electrode 420′. As shown in FIG. 18, the spacers 700 may be formed over the mask layer 225.

The spacers 700 may include spacer material such as silicon oxide, silicon nitride, silicon carbide, silicon oxynitride, SiCN films, silicon oxycarbide, SiOCN films, and/or combinations thereof. In some embodiments, each of the spacers 700 include multiple layers, such as a liner layer 710 and a main spacer layer 720 on a sidewall of the liner layer 710.

By way of example, the spacers 700 may be formed by depositing spacer material including a liner material layer 710 and a dielectric material layer 720 over the sacrificial gate structures 400′ using processes such as a subatmospheric CVD (SACVD) process, a flowable CVD process, an ALD process, a PVD process, or other suitable process respectively.

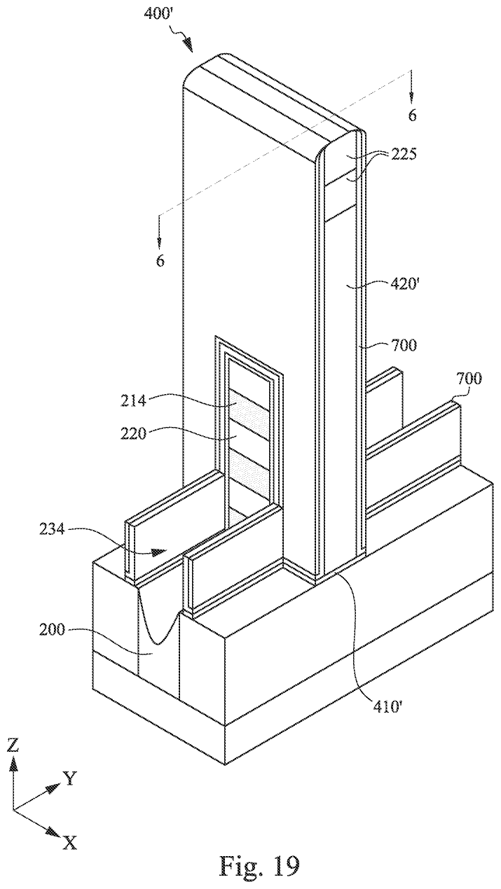

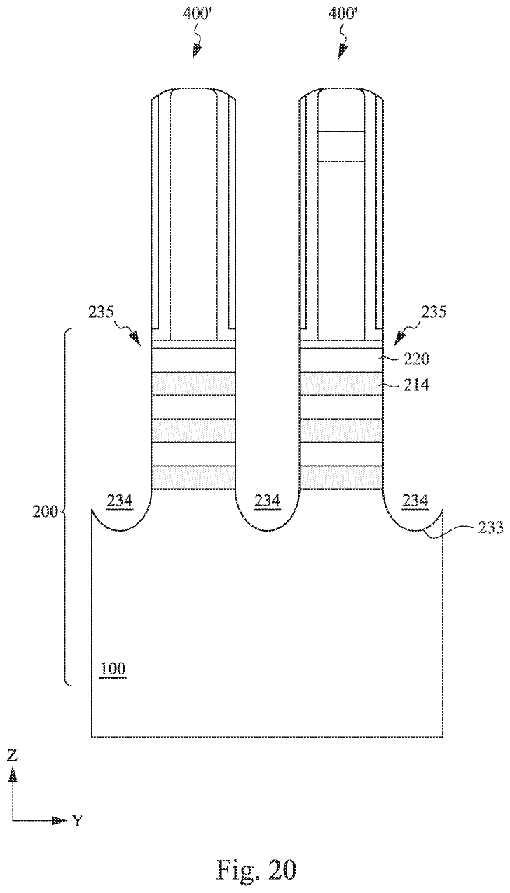

As shown in FIGS. 19 and 20, the deposition of the liner material layer 710 and the dielectric material layer 720 are followed by, at operation S920, an etching-back (e.g., anisotropic) process to expose, and remove, portions 200a of the fins 200 adjacent to and not covered by the sacrificial gate structure 400′ (e.g., source/drain regions). Specifically, the method 900 (FIG. 4) recesses the portions of the fin 200 not covered by the sacrificial gate structures 400′ to form cavities, gaps, or recesses 234 in the source/drain regions. It is noted that FIG. 19 shows only one sacrificial gate structure 400′ and the adjacent portion of fin 200 so that etching of the S/D region between the sacrificial gate structures 400′ of FIG. 18 may be more clearly viewed. FIG. 20 is a cross sectional-view along line 6-6 in FIG. 19 but, like FIG. 18, FIG. 20 illustrates both sacrificial gate structures 400′ and the fin 200 adjacent to both sacrificial gate structures 400′.

The liner material layer 710 and the dielectric material layer 720 may remain on the sidewalls of the sacrificial gate structure 400′ as the gate sidewall spacers 700, and on the sidewalls of the fins 200 as the fin sidewall spacers 700. In some embodiments, the etching-back process may include a wet etch process, a dry etch process, a multiple-step etch process, and/or a combination thereof. The spacers 700 may have a thickness ranging from 5 to 20 nm.

As shown most clearly in FIG. 20, the stacked epitaxial layers 214 and 220 and an upper portion of substrate 100 forming fin 200 are etched down at the S/D regions. As a result, a bottom gap surface 233 is formed in the fin 200. In some embodiments, the operation S920 forms the gaps 234 by a suitable etching process, such as a dry etching process, a wet etching process, or a combination thereof. As a result of the etching process, fin segments 235 of the upper portion of the fin 200 are defined and separated from one another by the gaps 234.

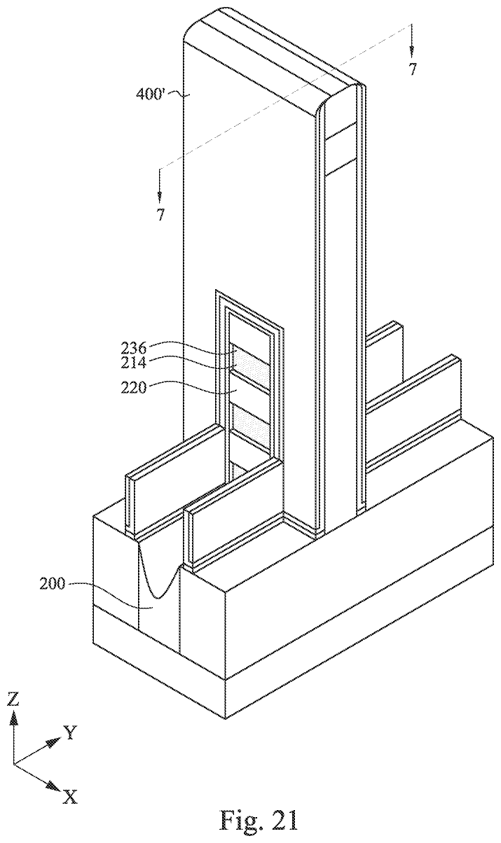

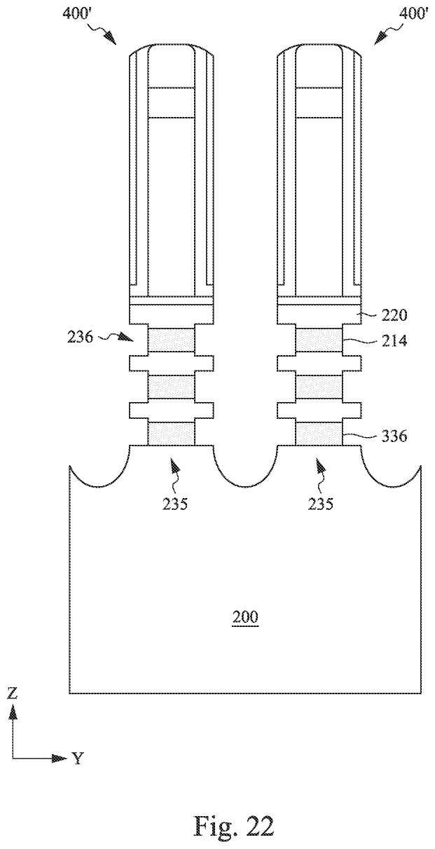

As shown in FIGS. 21 and 22, at operation S922, the method 900 (FIG. 4) etches the lateral ends of the epitaxial layers 214 in the Y-direction to recessed surfaces 336, thereby forming cavities 236.

It is noted that FIG. 21, similar to FIG. 19, shows only one sacrificial gate structure 400′ and the adjacent portion of fin 200 and so that etching of the source/drain region between the sacrificial gate structures 400′ may be viewed.

FIG. 22 is a cross-sectional view along line 7-7 of the structure in FIG. 21 but, like FIGS. 18 and 20, illustrates both sacrificial gate structures 400′ and the adjacent fin 200.

The epitaxial layers 214 may be selectively etched by using a wet etchant such as, but not limited to, ammonium hydroxide (NH4OH), tetramethylammonium hydroxide (TMAH), ethylenediamine pyrocatechol (EDP), potassium hydroxide (KOH), HF, O3, H2O2, or HCl solutions. Alternatively, the operation S922 may first selectively oxidize lateral ends of the epitaxial layers 214 that are exposed in the gaps 234 to increase the etch selectivity between the epitaxial layers 214 and 220. In some examples, the oxidation process may be performed by exposing the GAA device 1000 to a wet oxidation process, a dry oxidation process, or a combination thereof.

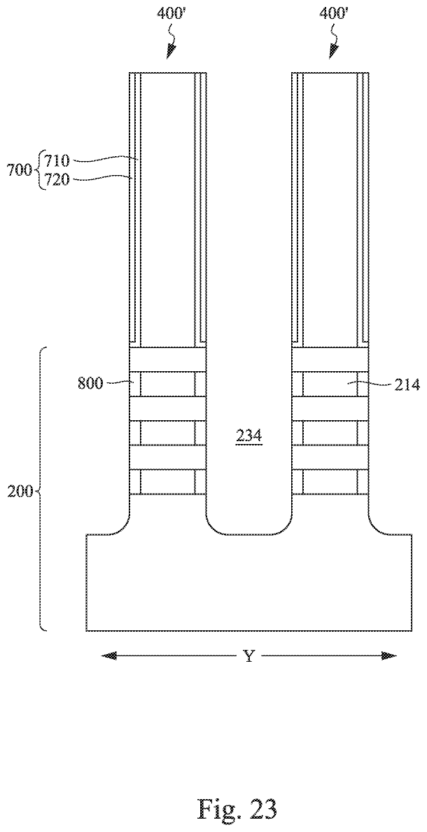

As shown in FIG. 23, method 900 may continue with operation S924 which forms inner spacers 800 laterally adjacent to the epitaxial layers 214. For example, an inner spacer material layer or layers may be deposited in the gap on the gap sidewalls, including on the lateral ends of the epitaxial layer 214. The inner spacer material may include silicon oxides, silicon nitrides, silicon carbides, silicon carbide nitride, silicon oxide carbide, silicon carbide oxynitride, and/or other suitable dielectric materials. In some embodiments, the inner spacer material layer is deposited as a conformal layer. The inner spacer material layer may be formed by ALD or any other suitable method. Further, operation S924 may include trimming the inner spacer material to form the inner spacers 800. Removal of the portions of the inner spacer material may be performed by an etching process, such as an anisotropic etching process, for example a dry etching process.

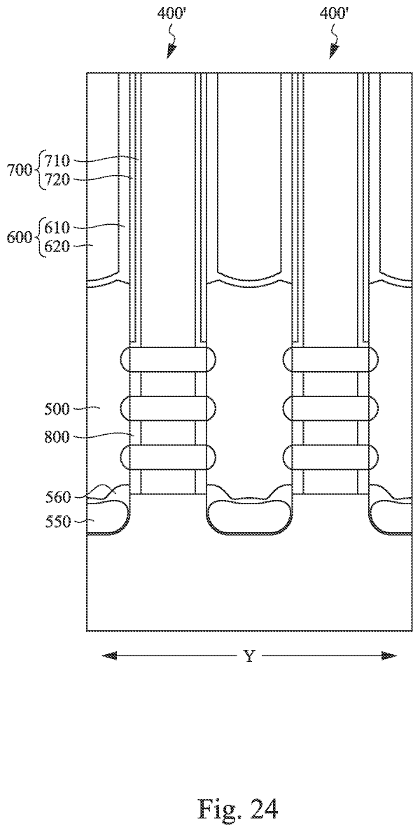

As shown in FIG. 24, method 900 may continue with operation S926 which forms a bottom epitaxial region 550 in the gaps 234. For example, a semiconductor material may be grown on the gap bottom surface. For example, undoped silicon may be grown as epitaxial semiconductor material on the gap bottom surface. Further, operation S926 may include etching a portion of the semiconductor material. Also, a bottom dielectric layer 560 may be formed over the bottom epitaxial region 550, as shown. For example, a dielectric material may be deposited and trimmed to form the bottom dielectric layer 560. As shown, the bottom dielectric layer 560 may contact and extend between the lowest opposite inner spacers 800.

Further, as shown in FIG. 24, method 900 (FIG. 4) may continue with operation S928 which grows epitaxial material in the recesses to form source/drain structures 500. It is noted that the source/drain structures 500 may be formed by successive formed layers. Also, the source/drain structures 500 may be formed with layers selected for use in an NFET or PFET. The epitaxial source/drain structures 500 may be formed by an epitaxial growth method using CVD, ALD or molecular beam epitaxy (MBE). The epitaxial structures 500 may include SiGe for PFETs, and silicon for NFETs.

As further shown in FIG. 24, method 900 (FIG. 4) may continue with operation S930 which forms interlayer dielectric structure 600 over the source/drain structures 500 and between spacer structures 700. In some embodiments, the interlayer dielectric structure 600 includes a layer 610 and a layer 620.

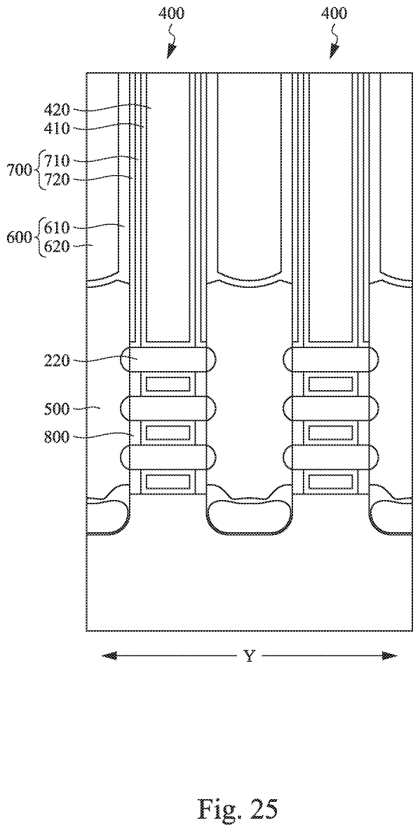

As shown in FIG. 25, method 900 (FIG. 4) may continue with operation S932 which includes performing a replacement metal gate process. Specifically, the sacrificial gates 400′, including the sacrificial gate electrode 420′ and the sacrificial gate dielectric 410′, and the sacrificial layers 214 are removed. Further, metal gates 400 are formed in the replacement metal gate process. Metal gates 400 include a gate dielectric layer 410, such as a high-K gate dielectric, and a metal electrode 420. After removal of the sacrificial layers 214 and formation of the metal gates 400, the remaining epitaxial layers 220 may be referred to as semiconductor nanosheets 220. As shown, the gate dielectric 410 may be formed around the nanosheets 220, and the metal gate electrode material 420 may be deposited over the gate dielectric 410 to form the metal gate 400. As shown, the metal gate 400 abuts the inner spacers 800.

In certain embodiments, the replacement metal gate process may include a wire-release process to form vertically-spaced nanosheets, in accordance with some embodiments. The wire release process step may also be referred to as a sheet release process step, a sheet formation process step, a nanosheet formation process step or a wire formation process step. In an embodiment the first layers 214 may be removed using a wet etching process that selectively removes the material of the first layers (e.g., silicon germanium (SiGe)) without significantly removing the material of the second layers 220 (e.g., silicon (Si)). However, any suitable removal process may be utilized.

For example, in an embodiment, an etchant such as a high temperature HCl may be used to selectively remove the material of the first layers 214 (e.g., SiGe) without substantively removing the material of the second layers 220 (e.g., Si). Additionally, the wet etching process may be performed at a temperature of from 400° C. to 600° C., such as about 560° C., and for a time of from 100 seconds to 600 seconds, such as about 300 seconds. However, any suitable etchant, process parameters, and time can be utilized.

According to some embodiments, the gate dielectric 410 comprises a high-K material (e.g., a material with a K value greater than or equal to 9) such as Ta₂O₅, Al₂O₃, Hf oxides, Ta oxides, Ti oxides, Zr oxides, Al oxides, La oxides (e.g., HfO₂, HfSiO, HfSiON, HfTaO, HfTiO, HfZrO, LaO, ZrO, TiO), combinations of these, or the like, deposited through a process such as atomic layer deposition, chemical vapor deposition, or the like. In some embodiments, the gate dielectric 410 comprises a nitrogen doped oxide dielectric that is initially formed prior to forming a metal content high-K (e.g., K value>13) dielectric material. The gate dielectric 410 may be deposited to a thickness of from 1 to 3 nm, although any suitable material and thickness may be utilized.

According to some embodiments, the metal electrode 420 is formed using multiple layers, each layer deposited sequentially adjacent to each other using a highly conformal deposition process such as atomic layer deposition, although any suitable deposition process may be utilized. According to some embodiments, a capping layer, a barrier layer, an n-metal work function layer, a p-metal work function layer, and a fill material may be provided.

The capping layer may be formed adjacent to the gate dielectric 410 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as atomic layer deposition, chemical vapor deposition, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAIN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The n-metal work function layer may be formed adjacent to the barrier layer. In an embodiment the n-metal work function layer is a material such as W, Cu, AlCu, TiAlC, TiAlN, TiAl, Pt, Ti, TiN, Ta, TaN, Co, Ni, Ag, Al, TaAl, TaAlC, TaC, TaCN, TaSiN, Mn, Zr, other suitable n-type work function materials, or combinations thereof. For example, the first n-metal work function layer may be deposited utilizing an atomic layer deposition (ALD) process, CVD process, or the like. However, any suitable materials and processes may be utilized to form the n-metal work function layer.

The p-metal work function layer may be formed adjacent to the n-metal work function layer. In an embodiment, the first p-metal work function layer may be formed from a metallic material such as W, Al, Cu, TIN, Ti, TiAlN, TiAl, Pt, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the p-metal work function layer may be deposited using a deposition process such as atomic layer deposition, chemical vapor deposition, or the like, although any suitable deposition process may be used.

After the p-metal work function layer has been formed, the fill material is deposited to fill a remainder of the opening. In an embodiment the fill material may be a material such as tungsten, Al, Cu, AlCu, W, Ti, TiAlN, TiAl, Pt, TaC, TaCN, TaSiN, Mn, Zr, TiN, Ta, TaN, Co, Ni, combinations of these, or the like, and may be formed using a deposition process such as plating, chemical vapor deposition, atomic layer deposition, physical vapor deposition, combinations of these, or the like. However, any suitable material may be utilized.

After the openings resulting from the removal of the dummy gates 400′ have been filled, the materials of the metal electrode 420 and the gate dielectric 410 may be planarized in order to remove any material that is outside of the openings resulting from the removal of the dummy gates 400′. In a particular embodiment, the removal may be performed using a planarization process such as chemical mechanical polishing, although any suitable planarization and removal process may be utilized. According to some embodiments, the metal gates 400 may be formed to a vertical height, in the Z-direction, of from 70 nm to 85 nm. However, any suitable height may be used.

Method 900 (FIG. 4) may continue with operation S934 which includes performing further processing for completing semiconductor devices, interconnection thereof and other typical Back-End-Of-Line (BEOL) processing.

In an embodiment, a method is provided and includes forming structures over a substrate; forming a layer between the structures; performing a first etch process to recess the layer to a surface having a serrated profile; optionally forming a film or films over the surface, wherein the film or films retain the serrated profile; depositing a material over the substrate; and performing a second etch process to etch a portion of the material and form the material with a sidewall, wherein the second etch process uncovers the serrated profile, and wherein during the second etch process ions are reflected from the serrated profile.

In some embodiments of the method, the structures include a first structure having a first sidewall and a second structure having a second sidewall; the portion of the material removed by the second etch process extends from the first sidewall to the second sidewall; and during the second etch process, ions are reflected from the serrated profile to remove material on the first sidewall and the second sidewall.

In some embodiments of the method, the structures include a first structure having a first sidewall; after the second etch process, a residue of the material remains on the first sidewall above the serrated profile; the residue has a thickness in a lateral direction perpendicular to the first sidewall; and the thickness is less than 4 nanometers (nm).

In some embodiments of the method, the structures include a first structure having a first sidewall; the first structure includes a mesa portion included of a first semiconductor material, a second semiconductor layer over the mesa portion, and a first semiconductor layer over the second semiconductor layer; after the second etch process, a residue of the material remains on the first sidewall; and the residue does not contact the first semiconductor layer.

In some embodiments of the method, the second etch process includes: selectively masking the material to define a masked portion of the material and an unmasked portion of the material, wherein the second etch process removes the unmasked portion of the material.

In some embodiments of the method, the first etch process includes cycles of a chemical etch and a plasma etch.

In some embodiments of the method, the first etch process uses an etchant gas selected from NH3, NF3, HBr, and H2; a passivation gas selected from N2 and O2; and a dilute gas selected from He, Ar, and N2.

In some embodiments of the method, the first etch process is performed at a power of from 10 to 4000 Watts; at a pressure of from 10 mTorr to 3 Torr; and with a gas flow of from 20 to 3000 sccm.

In another embodiment, a method includes forming a first fin structure and a second fin structure; forming an isolation region between the first fin structure and the second fin structure; recessing the isolation region to provide the isolation region with a recessed surface having a wave shape; depositing a sacrificial gate material over the isolation region; and etching a portion of the sacrificial gate material to form a sacrificial gate.

In some embodiments of the method, the wave shape includes: a first terminal crest abutting the first fin structure; a second terminal crest abutting the second fin structure; a first intermediate crest located between the first terminal crest and the second terminal crest; and a second intermediate crest located between the first intermediate crest and the second terminal crest.

In some embodiments of the method, the wave shape further includes a first terminal trough located between the first terminal crest and the first intermediate crest; a second terminal trough located between the second terminal crest and the second intermediate crest; and a central trough located between the first intermediate crest and the second intermediate crest.

In some embodiments of the method, each fin structure includes a mesa portion of a first semiconductor material and a second layer of a second semiconductor material, the mesa portion has an uppermost surface, the first terminal trough is located at a first vertical depth from the uppermost surface; the second terminal trough is located at a second vertical depth from the uppermost surface; the central trough is located at a central vertical depth from the uppermost surface; and the central vertical depth is greater than the first vertical depth and the second vertical depth.

In some embodiments of the method, the first terminal trough is from 10 to 20 nm; the second terminal trough is from 10 to 20 nm; and the central trough is from 15 to 35 nm.

In some embodiments of the method, the first terminal trough is from 20 to 30 nm; the second terminal trough is from 20 to 30 nm; and the central trough is from 25 to 45 nm.

In some embodiments of the method, the first fin structure has a sidewall; an angle is defined between the sidewall and the recessed surface; and the angle is from 120 to 160 degrees.

In another embodiment, a gate-all-around (GAA) device is provided and includes a first dielectric region distanced from a second dielectric region in a longitudinal Y-direction; a first source/drain region distanced from a second source/drain region in a lateral X-direction, wherein the first source/drain region is located between the first dielectric region and the second dielectric region; a fin structure including a semiconductor nanosheet distanced from a mesa portion in a vertical Z-direction, wherein the semiconductor nanosheet extends in the lateral X-direction from the first source/drain region to the second source/drain region; a gate structure overlying the fin structure, wherein the gate structure includes a metal gate and a high-k gate dielectric, wherein the gate structure extends in the longitudinal Y-direction, and wherein a lowest portion of the gate structure is located between the mesa portion and the semiconductor nanosheet; a first inner spacer separating the first source/drain region from the lowest portion of the gate structure in the lateral X-direction; a first spacer structure separating the first dielectric region from the gate structure in the lateral X-direction; and a second spacer structure separating the second dielectric region from the gate structure in the lateral X-direction; wherein a minimum first distance between the first spacer structure and the first inner spacer in the longitudinal Y-direction is from 0 to 2 nanometers (nm); and wherein a minimum second distance between the second spacer structure and the first inner spacer in the longitudinal Y-direction is from 0 to 2 nanometers (nm).

In some embodiments of the device, the minimum first distance is located at an interface, the metal gate extends toward the interface to an edge, and a lateral profile of the edge of the metal gate has an internal angle of greater than 100 degrees.

In some embodiments of the device, a minimum first distance is located at an interface, the metal gate extends toward the interface to an edge, and a lateral profile of the edge of the metal gate has an internal angle of from 100 to 120 degrees.

In some embodiments, the device further includes a first shallow isolation region distanced from a second shallow isolation region in the longitudinal Y-direction; wherein the mesa portion of the fin structure is located between the first shallow isolation region and the second shallow isolation region; the mesa portion of the fin structure has a sidewall abutting the first shallow isolation region; the first shallow isolation region has an uppermost surface; an angle is defined between the sidewall and the uppermost surface; and the angle is from 120 to 160 degrees.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
forming structures over a substrate;
forming a layer between the structures;
performing a first etch process to recess the layer to a surface having a serrated profile;
optionally forming a film or films over the surface, wherein the film or films retain the serrated profile;
depositing a material over the substrate; and
performing a second etch process to etch a portion of the material and form the material with a sidewall, wherein the second etch process uncovers the serrated profile, and wherein during the second etch process ions are reflected from the serrated profile.

2. The method of claim 1 wherein:
the structures comprise a first structure having a first sidewall and a second structure having a second sidewall;
the portion of the material removed by the second etch process extends from the first sidewall to the second sidewall; and
during the second etch process, ions are reflected from the serrated profile to remove material on the first sidewall and the second sidewall.

3. The method of claim 1 wherein:
the structures comprise a first structure having a first sidewall;
after the second etch process, a residue of the material remains on the first sidewall above the serrated profile;
the residue has a thickness in a lateral direction perpendicular to the first sidewall; and
the thickness is less than 4 nanometers (nm).

4. The method of claim 1 wherein:
the structures comprise a first structure having a first sidewall;
the first structure comprises a mesa portion comprised of a first semiconductor material, a second semiconductor layer over the mesa portion, and a first semiconductor layer over the second semiconductor layer;
after the second etch process, a residue of the material remains on the first sidewall; and
the residue does not contact the first semiconductor layer.

5. The method of claim 1, wherein the second etch process includes:
selectively masking the material to define a masked portion of the material and an unmasked portion of the material, wherein the second etch process removes the unmasked portion of the material.

6. The method of claim 1, wherein the first etch process comprises cycles of a chemical etch and a plasma etch.

7. The method of claim 6, wherein the first etch process uses:
an etchant gas selected from NH3, NF3, HBr, and H2;
a passivation gas selected from N2 and O2; and
a dilute gas selected from He, Ar, and N2.

8. The method of claim 7, wherein the first etch process is performed:
at a power of from 10 to 4000 Watts;
at a pressure of from 10 mTorr to 3 Torr; and
with a gas flow of from 20 to 3000 sccm.

9. A method comprising:
forming a first fin structure and a second fin structure;
forming an isolation region between the first fin structure and the second fin structure;
recessing the isolation region to provide the isolation region with a recessed surface having a wave shape;
depositing a sacrificial gate material over the isolation region; and
etching a portion of the sacrificial gate material to form a sacrificial gate.

10. The method of claim 9, wherein the wave shape comprises:
a first terminal crest abutting the first fin structure;
a second terminal crest abutting the second fin structure;
a first intermediate crest located between the first terminal crest and the second terminal crest; and
a second intermediate crest located between the first intermediate crest and the second terminal crest.

11. The method of claim 10, wherein the wave shape further comprises:
a first terminal trough located between the first terminal crest and the first intermediate crest;
a second terminal trough located between the second terminal crest and the second intermediate crest; and
a central trough located between the first intermediate crest and the second intermediate crest.

12. The method of claim 11, wherein each fin structure includes a mesa portion of a first semiconductor material and a second layer of a second semiconductor material, wherein the mesa portion has an uppermost surface, and wherein:
the first terminal trough is located at a first vertical depth from the uppermost surface;
the second terminal trough is located at a second vertical depth from the uppermost surface;
the central trough is located at a central vertical depth from the uppermost surface; and
the central vertical depth is greater than the first vertical depth and the second vertical depth.

13. The method of claim 12, wherein:
the first terminal trough is from 10 to 20 nm;
the second terminal trough is from 10 to 20 nm; and
the central trough is from 15 to 35 nm.

14. The method of claim 12, wherein:
the first terminal trough is from 20 to 30 nm;
the second terminal trough is from 20 to 30 nm; and
the central trough is from 25 to 45 nm.

15. The method of claim 9, wherein:
the first fin structure has a sidewall;
an angle is defined between the sidewall and the recessed surface; and
the angle is from 120 to 160 degrees.

16. The method of claim 9, wherein recessing the isolation region to provide the isolation region with the recessed surface having the wave shape comprises performing an etch process using an etchant gas selected from NH3, NF3, HBr, and H2; using a passivation gas selected from N2 and O2; and using a dilute gas selected from He, Ar, and N2, at a power of from 10 to 4000 Watts; at a pressure of from 10 mTorr to 3 Torr; and with a gas flow of from 20 to 3000 sccm.

17. A gate-all-around (GAA) device comprising:
a first dielectric region distanced from a second dielectric region in a longitudinal Y-direction;
a first source/drain region distanced from a second source/drain region in a lateral X-direction, wherein the first source/drain region is located between the first dielectric region and the second dielectric region;
a fin structure including a semiconductor nanosheet distanced from a mesa portion in a vertical Z-direction, wherein the semiconductor nanosheet extends in the lateral X-direction from the first source/drain region to the second source/drain region;
a gate structure overlying the fin structure, wherein the gate structure includes a metal gate and a high-k gate dielectric, wherein the gate structure extends in the longitudinal Y-direction, and wherein a lowest portion of the gate structure is located between the mesa portion and the semiconductor nanosheet;
a first inner spacer separating the first source/drain region from the lowest portion of the gate structure in the lateral X-direction;
a first spacer structure separating the first dielectric region from the gate structure in the lateral X-direction; and
a second spacer structure separating the second dielectric region from the gate structure in the lateral X-direction;
wherein a minimum first distance between the first spacer structure and the first inner spacer in the longitudinal Y-direction is from 0 to 2 nanometers (nm); and
wherein a minimum second distance between the second spacer structure and the first inner spacer in the longitudinal Y-direction is from 0 to 2 nanometers (nm).

18. The GAA device of claim 17, wherein the minimum first distance is located at an interface, wherein the metal gate extends toward the interface to an edge, and wherein a lateral profile of the edge of the metal gate has an internal angle of greater than 100 degrees.

19. The GAA device of claim 17, wherein a minimum first distance is located at an interface, wherein the metal gate extends toward the interface to an edge, and wherein a lateral profile of the edge of the metal gate has an internal angle of from 100 to 120 degrees.

20. The GAA device of claim 17 further comprising a first shallow isolation region distanced from a second shallow isolation region in the longitudinal Y-direction; wherein:
the mesa portion of the fin structure is located between the first shallow isolation region and the second shallow isolation region;
the mesa portion of the fin structure has a sidewall abutting the first shallow isolation region;
the first shallow isolation region has an uppermost surface;
an angle is defined between the sidewall and the uppermost surface; and
the angle is from 120 to 160 degrees.
